(19) United States
(12) Patent Application Publication
(10) Pub. No.: US 2010/0127393 A1
(43) Pub. Date: May 27, 2010

(54) Electronic device and semiconductor device

(75) Inventor: Seiya Fujii, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/591,346

(22) Filed: Nov. 17, 2009

(30) Foreign Application Priority Data
Nov. 25, 2008 (JP) P2008-299277

(51) Int. Cl. H01L 23/498; H05K 1/11

(52) U.S. Cl. 257/737; 174/261; 257/E23.068

(57) ABSTRACT

An electronic device includes: a wiring board having first and second regions; a plurality of first lands in the first region; a plurality of second lands in the second region; and an insulator covering the wiring board. More heat is applied to the first region than the second region. The second land is smaller in volume than the first land. The insulator has a plurality of openings being adjacent to the plurality of first lands and the plurality of second lands. Each of the plurality of openings has substantially the same area.

### BACKGROUND OF THE INVENTION

1. Field of the Invention

The present invention relates to an electronic device and a semiconductor device.

Priority is claimed on Japanese Patent Application No. 2008-299277, filed Nov. 25, 2008, the content of which is incorporated herein by reference.

2. Description of the Related Art

Generally, a BGA (Ball Grid Array) semiconductor device includes: a wiring board 2 having a surface 2a on which multiple lands 3 are provided and a surface 2b on which multiple connection pads 4 electrically connected to the lands 3 are provided; a semiconductor chip 5 mounted on the surface 2b of the wiring board 2; wires 7 electrically connecting electrode pads 6 on the semiconductor chip 5 and connection pads 4 on the wiring board 2; a seal 8 covering at least the semiconductor chip 5 and the wires 7; and solder balls 9 that are bumps on the lands 3, as shown in FIG. 5.

Recently, such a BGA semiconductor device 1 and components forming the semiconductor device 1 have been further miniaturized to meet the demand for thinner and denser semiconductor devices. For example, the solder ball 9 is substantially 0.3 mm in diameter.

The BGA semiconductor device 1 has a problem of poor connection of bumps, such as the solder balls 9, to be mounted on an external board for second mounting due to a decrease in the connection strength. One of the causes of the poor bump connection is a fluctuation in alloy growth between the bump and the land 3.

Generally, both overheating and insufficient heating causes insufficient alloy growth, thereby degrading the connection strength. Generally, bumps are mounted on the corresponding lands 3, and then the entire semiconductor device 1 is reflowed to implement bump connection.

The semiconductor device 5 is made of, for example, silicon having a specific heat capacity greater than that of the seal resin. For this reason, a difference in heating conditions occurs between the chip area where the semiconductor chip 5 is mounted and the chip-free area, thereby causing a fluctuation in alloy growth between the lands 3 under the chip area and the lands 3 under the chip-free area, resulting in a degradation of the connection strength.

To improve the poor bump connection, Japanese Patent Laid-Open Publication No. 2001-210749 (hereinafter, “Patent Document 1”) discloses a bump structure in which only corner bumps are made larger in size. Japanese Patent Laid-Open Publication No. H09-162531 (hereinafter, “Patent Document 2”) discloses a bump structure in which outermost bumps close to four corners are disposed along a concentric circle.

Further, Japanese Patent Laid-Open Publication No. 2000-243792 (hereinafter, “Patent Document 3”) discloses a BGA package including via holes in which lands outside the chip area are made larger to prevent resin from leaking through the via holes.

Concerning the bump structures disclosed in Patent Documents 1 and 2, the sizes and the positions of bumps are changed from a general grid arrangement, thereby requiring a design change of the lands on the external surface of the wiring board. The design change of the lands is against the demand for versatile semiconductor devices, thereby making it difficult to commercialize such a semiconductor device having the disclosed bump structure.

Further, Patent Document 3 does not disclose a technique of improving the connection strength in the case of a BGA semiconductor device having no via hole.

### SUMMARY

In one embodiment, an electronic device may include, but is not limited to: a wiring board having first and second regions; a plurality of first lands in the first region; a plurality of second lands in the second region; and an insulator covering the wiring board. More heat is applied to the first region than the second region. The second land is smaller in volume than the first land. The insulator has a plurality of openings being adjacent to the plurality of first lands and the plurality of second lands. Each of the plurality of openings has substantially the same area.

In another embodiment, a semiconductor device may include, but is not limited to: a wiring board having first and second regions; a plurality of first lands in the first region; a plurality of second lands in the second region; an insulator covering the wiring board; a semiconductor chip covering the second region; and a seal covering the first region and the semiconductor chip. The second land is smaller in volume than the first land. The insulator has a plurality of openings being adjacent to the plurality of first lands and the plurality of second lands. Each of the plurality of openings has substantially the same area. The seal and the semiconductor chip are on the same side with respect to the wiring board.

In still another embodiment, an electronic device may include, but is not limited to: a wiring board having first and second regions; a plurality of first lands in the first region; a plurality of second lands in the second region; and an insulator covering the wiring board. The second land is smaller in volume than the first land. The insulator has a plurality of openings being adjacent to the plurality of first lands and the plurality of second lands. Each of the plurality of openings has substantially the same area.

Accordingly, alloy growth between a land and a bump can be uniformed for every land to prevent poor bump connection without changing the conventional design, such as the arrangement of lands in a grid, the areas of openings included in the insulating film, and the sizes of the bumps.

In other words, the volume of the land outside the specific region is larger than that of the land inside the specific region, less heat being applied to the specific region than the other region, thereby achieving a uniform increase in temperature of every land. Therefore, a uniform alloy growth between the land and the bump is achieved for every land, thereby preventing a fluctuation in the connection strength.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view illustrating a semiconductor device according to a first embodiment of the present invention;

FIG. 2 is a plane view taken along a line A-A′ shown in FIG. 1;

FIG. 3 is a cross-sectional enlarged view illustrating bumps shown in FIG. 1;

FIG. 4 is a plane view taken along a line B-B′ shown in FIG. 3; and

FIG. 5 is a cross-sectional view illustrating a conventional semiconductor device.

### DETAILED DESCRIPTION OF THE PREFERRED EMBODIMENTS

The present invention will now be described herein with reference to illustrative embodiments. The accompanying drawings explain a semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

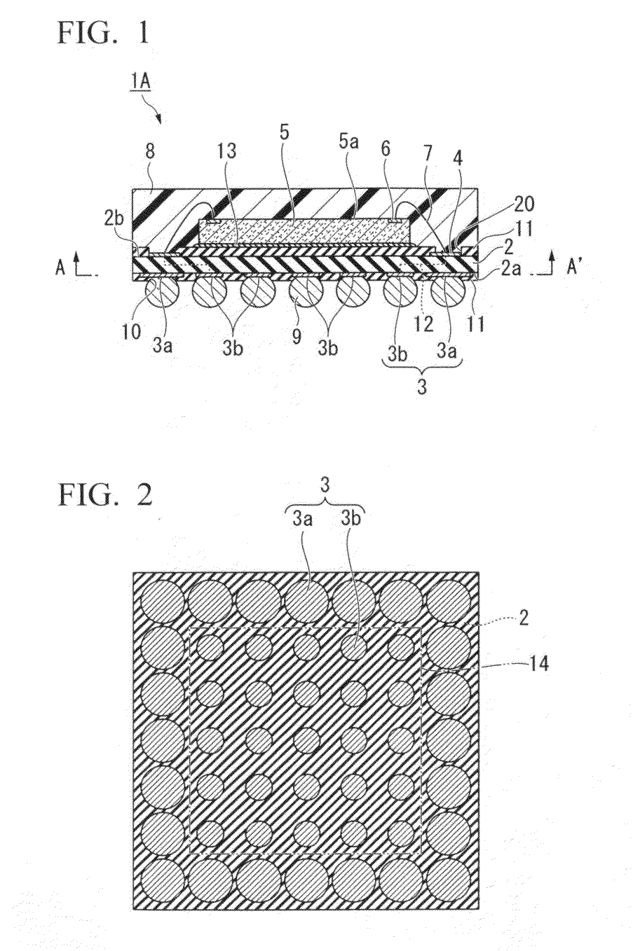

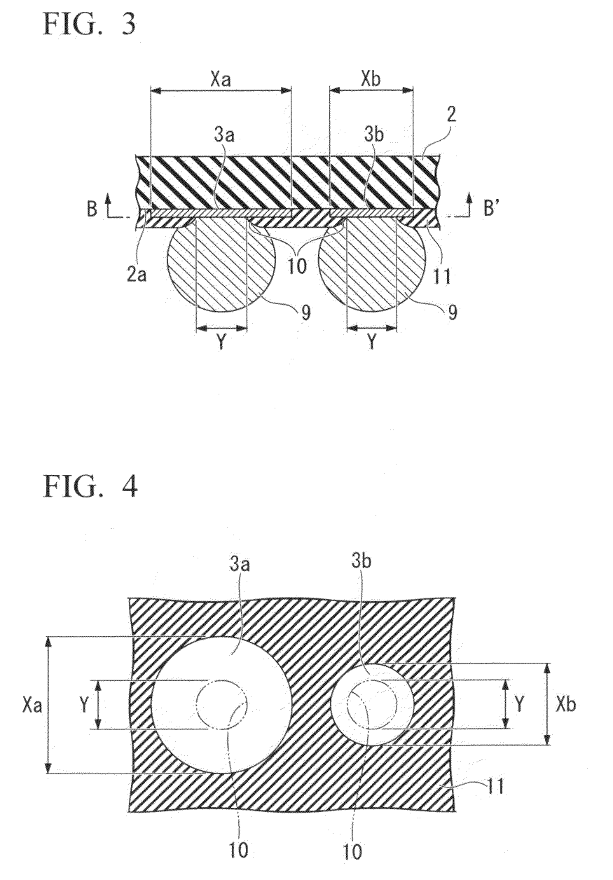

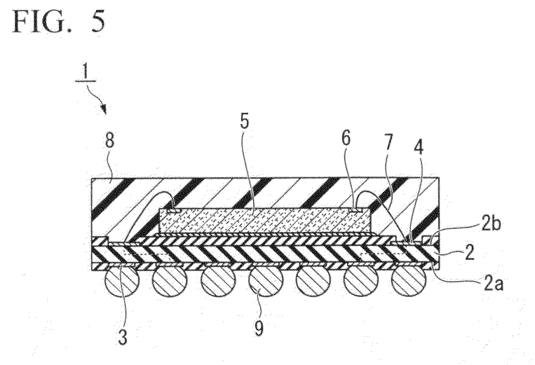

FIG. 1 is a cross-sectional view illustrating a semiconductor device 1A according to a first embodiment of the present invention. FIG. 2 is a plane view taken along a line A-A′ shown in FIG. 1. FIG. 3 is a cross-sectional enlarged view illustrating bumps shown in FIG. 1. FIG. 4 is a plane view taken along a line B-B′ shown in FIG. 3.

As shown in FIG. 1, the semiconductor device 1A is a BGA semiconductor device and includes: a wiring board 2 that is substantially rectangular in a plane view in the direction perpendicular to surfaces 2a and 2b of the wiring board 2; solder balls 9 that are bumps on the surface 2a of the wiring board 2; a semiconductor chip 5 on the surface 2b of the wiring board 2; and a seal 8 covering the semiconductor chip 5 and the surface 2b of the wiring board 2.

The wiring board 2 is a glass epoxy board having a thickness of, for example, 0.25 mm. Wires (not shown) are provided on both surfaces of the glass epoxy substrate. The wires are covered by a solder resist film 11 that is an insulating film having multiple openings 10, 20.

Multiple lands 3 cover the wires on the surface 2a seen through the openings 10. The land 3 is made of, for example, a Cu material and Ni/Au plating. As explained later, every opening 10 has substantially the same area. Multiple connection pads 4 cover the wires on the surface 2b seen through the openings 20.

The connection pads 4 are electrically connected to the corresponding lands 3 through internal wires 12 in the wiring board 2. The lands 3 are arranged in a grid at a given pitch, for example, the 1 mm pitch.

The semiconductor chip 5 is fixed on substantially the center of the surface 2b of the wiring board 2 through a fixing member 13, such as an insulating adhesive or a DAF (Die Attached Film).

The semiconductor chip 5 is substantially rectangular in a plane view in the direction perpendicular to the surface 2b of the wiring board 2. A circuit, such as a logic circuit or a memory circuit, is formed on a surface 5a of the semiconductor chip 5.

Multiple electrode pads-6 are provided on a periphery of the surface 5a of the semiconductor chip 5. A passivation film (not shown) covers the surface 5a excluding regions of the electrode pads 6 to protect the circuit formation surface.

The electrode pads 6 on the semiconductor chip 5 are electrically connected to the corresponding connection pads 4 on the wiring board 2 using conductive wires 7 made of, for example, Au or Cu.

Thus, the semiconductor chip 5 and the lands 3 are electrically connected through the wires 7, the connection pads 4, and the internal wires 12.

The seal 8 covers substantially the entire surface 2b so as to cover the semiconductor chip 5 and the wires 7. The seal 8 is made of a thermosetting resin, such as an epoxy resin. The seal 8 has a thickness of, for example, substantially 400 μm.

The solder balls 9 that are bumps are mounted on the corresponding lands 3 on the surface 2a of the wiring board 2.

As shown in FIGS. 1 to 4, the lands 3a are disposed outside a specific region 14 on the surface 2a corresponding to the chip region on the surface 2b on which the semiconductor chip 5 is mounted. The lands 3b are disposed inside the region 14.

The diameter Xa of the land 3a is greater than the diameter Xb of the land 3b. In other words, the land 3a has a larger area than the land 3b. Specifically, the area of the land 3a is 1.1 to 2.0 times larger than that of the land 3b.

The land 3a and the land 3b have the same thickness. Consequently, the land 3a has a larger volume than the land 3b. Specifically, the volume of the land 3a is 1.1 to 2.0 times larger than that of the land 3b.

The openings 10 inside and outside of the region 14 have the same diameter Y, and therefore have the same area. The solder balls 9 inside and outside of the region 14 are of the same size.

Since the semiconductor device 1A has the above structure, a specific heat capacity of the land 3a is greater than that of the land 3b. Consequently, the temperature of the lands 3a is prevented from increasing at the time of heating in a reflow process. For this reason, a fluctuation of alloy growth can be reduced, thereby achieving better bump connection.

The area ratio of the land 3a to the land 3b may be adequately adjusted in a range from 1.1 to 2.0 so that the degree of alloy growth and the degree of melting and solidification of the solder balls 9 are equalized between inside and outside of the region 14, thereby achieving better bump connection.

Specifically, the relationship between an increase in temperature and an amount of heat can be expressed as ΔT=Q/CM where ΔT denotes a variation in temperature, Q denotes heat, C denotes specific heat capacity, and M denotes mass. Since mass=volume×density, the above expression can be expressed as ΔT=Q/CVD, where V denotes volume, and D denotes density.

Assuming that the heat Q applied to the semiconductor device 1A (and respective lands 3) is constant, the lands 3 are made of the same material, and the specific heat capacity C and the density D are constant, the above expression can be expressed as ΔT=α/V, where α denotes a constant value.

Further, assuming that the volume V=area×thickness, and the lands 3 have the same thickness, the above expression can be expressed as ΔT=β/S , where β denotes a constant value, and S denotes the area.

As understood from the expression, an increase in temperature of the land 3 is inversely proportional to the area of the land 3. Melting of bump and alloy growth between the land 3 and the bump are correlated to the temperature of the land 3. A variation in the temperature of each land 3 can be controlled by changing the area of each land 3. For example, if the area of the land 3 doubles, the increase in the temperature of the land 3 is reduced by half (the effects of the wires on the substrate and peripheral atmosphere are ignored).

The semiconductor chip 5 has a specific heat capacity of approximately 700 J/kg√K, which is greater than that of the seal resin. Consequently, an increase in the temperature of the lands 3b is smaller than that of the lands 3a upon heating in a reflow process for bump connection or second mounting.

For this reason, the area of the land 3a is made larger so that the thermal behavior of the land 3a is the same as that of the land 3b. Thus, an increase in the temperature of the lands 3a is prevented, thereby achieving a uniform temperature of the lands 3a and 3b.

Consequently, alloy growth between every land 3 and the corresponding bump is equalized, thereby preventing a fluctuation of the connection strength, and therefore enhancing the connection reliability of the semiconductor device 1A.

Every opening 10 of the solder resist 10 has the same area with respect to any land 3. For this reason, every bump has the same shape, and therefore design change of lands on the surface 2b of the wiring board 2 is not necessary. Further, poor mounting and a decrease in the mounting reliability due to the change of the bump shape do not occur.

It is apparent that the present invention is not limited to the above embodiments, but may be modified and changed without departing from the scope and spirit of the invention.

For example, the size, the type, the number, and the mounting direction of the semiconductor chip, and the type of bumps are not limited to those of the embodiment. An element to be mounted in a package is not limited to the semiconductor chip, and another semiconductor package, such as a PiP (Package in Package), or passive and active elements may be used.

To further control the volumes of lands, lands in a specific area may be thicker, or via holes filled with, for example, Cu may be formed by etching the substrate. Moreover, the shape of the land is not limited to a circle, and a rectangular land may be used.

As used herein, the following directional terms “forward, rearward, above, downward, vertical, horizontal, below, and transverse” as well as any other similar directional terms refer to those directions of a device equipped with the present invention. Accordingly, these terms, as utilized to describe the present invention should be interpreted relative to a device equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

What is claimed is:

1. An electronic device comprising:
a wiring board having first and second regions, more heat being applied to the first region than the second region;
a plurality of first lands in the first region;
a plurality of second lands in the second region, the second land being smaller in volume than the first land; and
an insulator covering the wiring board, the insulator having a plurality of openings being adjacent to the plurality of first lands and the plurality of second lands, and the plurality of openings each having substantially the same area.

2. The electronic device according to claim 1, wherein
the first land has a first volume,
the second land has a second volume, and
the first volume is 1.1 to 2.0 times larger than the second volume.

3. A semiconductor device comprising:
a wiring board having first and second regions;
a plurality of first lands in the first region;
a plurality of second lands in the second region, the second land being smaller in volume than the first land;
an insulator covering the wiring board, the insulator having a plurality of openings being adjacent to the plurality of first lands and the plurality of second lands, and the plurality of openings each having substantially the same area;
a semiconductor chip covering the second region; and
a seal covering the first region and the semiconductor chip, the seal and the semiconductor chip being on the same side with respect to the wiring board.

4. The semiconductor device according to claim 3, wherein the second region is surrounded by the first region.

5. The semiconductor device according to claim 3, wherein the opening is smaller in area than the second land.

6. The semiconductor device according to claim 3, wherein
the plurality of first lands and the plurality of second lands have the same thickness, and
the first land is larger in area than the second land.

7. The semiconductor device according to claim 3, wherein
the first land has a first volume,
the second land has a second volume, and
the first volume is 1.1 to 2.0 times larger than the second volume.

8. The semiconductor device according to claim 3, wherein more heat is applied to the first region than the second region.

9. The semiconductor device according to claim 3, wherein
the seal has a first specific heat capacity, and
the semiconductor chip has a second specific heat capacity greater than the first specific heat capacity.

10. The semiconductor device according to claim 3, further comprising:
a plurality of same-sized bumps connecting to the plurality of first lands and the plurality of second lands through the plurality of openings, the plurality of same-sized bumps being on an opposite side of the semiconductor chip and the seal with respect to the wiring board.

11. An electronic device comprising:
a wiring board having first and second regions;
a plurality of first lands in the first region;
a plurality of second lands in the second region, the second land being smaller in volume than the first land; and
an insulator covering the wiring board, the insulator having a plurality of openings being adjacent to the plurality of first lands and the plurality of second lands, and the plurality of openings each having substantially the same area.

12. The electronic device according to claim 11, wherein the second region is surrounded by the first region.

13. The electronic device according to claim 11, wherein the opening is smaller in area than the second land.

14. The electronic device according to claim 11, wherein
the plurality of first lands and the plurality of second lands have the same thickness, and
the first land is larger in area than the second land.

15. The electronic device according to claim 11, wherein
the first land has a first volume,
the second land has a second volume, and
the first volume is 1.1 to 2.0 times larger than the second volume.

16. The electronic device according to claim 11, wherein more heat is applied to the first region than the second region.

17. The electronic device according to claim 11, wherein
the first region is a region for providing a first element over the first region, the first element having a first specific heat capacity, and
the second region is a region for providing a second element over the second region, the second element having a second specific heat capacity greater than the first specific heat capacity.

18. The electronic device according to claim 11, further comprising:
a semiconductor chip covering the second region; and
a seal covering the first region and the semiconductor chip, the seal and the semiconductor chip being on the same side with respect to the wiring board.

19. The electronic device according to claim 18, further comprising:
a plurality of same-sized bumps connecting to the plurality of first lands and the plurality of second lands through the plurality of openings, the plurality of same-sized bumps being on an opposite side of the semiconductor chip and the seal with respect to the wiring board.
